(19) United States
(12) Patent Application Publication
(10) Pub. No.: US 2003/0033570 A1
(43) Pub. Date: Feb. 13, 2003

(54) Method and apparatus for encoding and decoding low density parity check codes and low density turbo product codes

(76) Inventors: Roman R. Khannanov, Moscow (RU); Garik Markarian, Chilworth (GB); Sergey I. Ortyukov, Moscow (RU); Keith Pickavace, Romsey (GB); Sergey L. Portney, Moscow (RU)

Correspondence Address: HAVERSTOCK & OWENS LLP, 162 North Wolfe Road, Sunnyvale, CA, 94086, US

(21) Appl. No.: 10/143,254

(22) Filed: May 9, 2002

Related U.S. Application Data
(60) Provisional application No. 60/289,905, filed on May 9, 2001.

(51) Int. Cl. H03M 13/00

(52) U.S. Cl. 714/755

(57) ABSTRACT

A method of and apparatus for encoding a one dimensional input codeword into an output codeword, wherein the output codeword includes an output codeword bit comprising the steps of receiving the input codeword, wherein the input codeword includes an input codeword bit; creating a generator matrix, wherein the generator matrix includes a parity matrix having a plurality of parity bits; combining the input codeword bit and a corresponding parity bit from the plurality of parity bits, thereby generating an output redundant bit associated with the output codeword bit; transmitting the input codeword bit; and transmitting the output redundant bit.

### RELATED APPLICATION

This Patent Application claims priority under 35 U.S.C. 119 (e) of the co-pending U.S. Provisional Patent Application Serial No. 60/289,905 filed May 9, 2001, and entitled “METHOD AND APPLICATION OF LOW DENSITY PARITY CHECK CODES AND THEIR EXTENSIONS TO LOW DENSITY TURBO PRODUCT CODES TO THE PROTECTION OF DATA IN COMMUNICATIONS SYSTEMS”. The Provisional Patent Application Serial No. 60/289,905 filed May 9, 2001, and entitled “METHOD AND APPLICATION OF LOW DENSITY PARITY CHECK CODES AND THEIR EXTENSIONS TO LOW DENSITY TURBO PRODUCT CODES TO THE PROTECTION OF DATA IN COMMUNICATIONS SYSTEMS” is also hereby incorporated by reference.

### FIELD OF THE INVENTION

The present invention relates to the field of linear block codes, in general, and in particular, a method of and apparatus for encoding and decoding low density parity check codes and low density turbo product codes.

### BACKGROUND OF THE INVENTION

Low density parity check (LDPC) codes were first thought about in 1962. Since that time, there has been a substantial amount of mathematical knowledge about such LDPC codes. LDPC codes have natural uses in all areas of communication systems and are especially suited to scenarios where long block lengths of codes are to be used for extra performance requirements. However, LDPC codes have laid dormant due to many reasons, such as the recent invention of the Viterbi algorithm which is a practically realizable algorithm for decoding convolutional codes. In addition, LDPC codes were not easily implementable. LDPC codes are one dimensional codes that have a very long block length such that encoders and decoders have been unable to utilize them in an efficient manner due to the requirement of storing such long block lengths in their respective memories. Further, the complexity, randomness of bits and long block lengths of LDPC codes were not easily handled by the encoders, decoders and processing units of many electronic devices. However, LDPC codes give better results than conventional Viterbi and Turbo Product Codes because of their longer block length and more random nature of their coding scheme. Much more theoretical work was completed in which ideas were independently reinvented such that much faster processors are now available to be used in a practical situation. However, encoding and decoding schemes are only utilized towards product codes, extended hamming codes and turbo product codes. In addition, encoding and decoding schemes are not present which are utilized towards LDPCs and low density turbo product codes (LDTPCs). What is needed is an encoding and decoding scheme which is utilized towards LDPCs and LDTPCs.

### SUMMARY OF THE INVENTION

In one aspect of the present invention, a method of encoding a one dimensional input codeword into an output codeword. The output codeword includes an output codeword bit comprising the following steps. Receiving the input codeword, wherein the input codeword includes an input codeword bit. Creating a generator matrix, wherein the generator matrix includes a parity matrix that has a plurality of parity bits. Combining the input codeword bit with a corresponding parity bit from the plurality of parity bits. This generates an output redundant bit that is associated with the output codeword bit. Transmitting the input codeword bit as well as the output redundant bit. Other features and advantages of the present invention will become apparent after reviewing the detailed description of the preferred embodiments set forth below.

### BRIEF DESCRIPTION OF THE DRAWINGS

FIG. 1 illustrates an overall block diagram of the encoder and decoder system in accordance with the present invention.

FIG. 2 illustrates a generator matrix having dimensions (n, k) in accordance with the present invention.

FIG. 3a illustrates a flow chart related to the encoding method in accordance with the present invention.

FIG. 3b illustrates a parity matrix having dimension (n, n−k) in accordance with the present invention.

FIG. 4 illustrates a timing diagram of the decoding method with respect to LDPC codes in accordance with the present invention.

FIG. 5 illustrates a general LDTPC block matrix in accordance with the present invention.

### DETAILED DESCRIPTION OF THE PREFERRED EMBODIMENT

Reference will now be made in detail to the preferred and alternative embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it should be noted that the present invention may be practiced without these specific details. In other instances, well known methods, procedures, components, and circuits have not been described in detail as not to unnecessarily obscure aspects of the present invention.

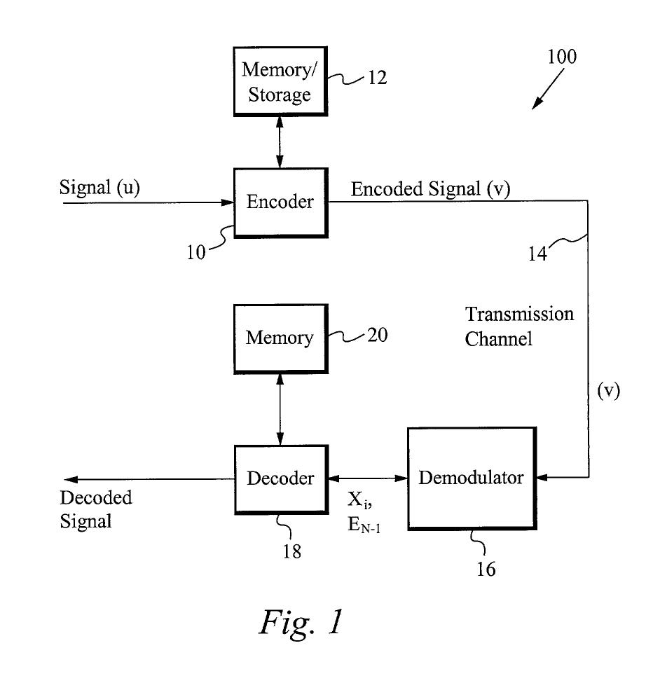

FIG. 1 shows a general overall block diagram of the overall encoding and decoding system 100 of the present invention. In the preferred embodiment, the unencoded LDPC codes enter the encoder module 10 wherein the data is encoded. The LDPC codes enter as one dimensional codeword vectors u having information bits uₙ. The encoder 10 is preferably coupled to a memory 12 which preferably stores the parity matrix which is used to encode the LDPC data, as will be discussed in more detail below. This is such that the system 100 does not need to wait for the whole codeword u to enter the system before encoding the matrix. Alternatively, the memory 12 stores the actual u information codeword as well as the parity bits. Once the LDPC code is encoded, the encoded data codewords v are sent over a transmission channel 14 to a receiving end which includes a demodulator 16, decoder 18 and memory 20.

Due to noise present in the transmission channel 14, the received encoded block of data v is demodulated by the demodulator 16 which then supplies the decoder 18 with hard decision and soft decision values. The decoder 18 decodes the encoded data by using an iterative decoding scheme and a parity check matrix in the LDPC code. It is preferred that the decoder 18 is a Soft In/Soft Out (SISO) decoder, which receives demodulated soft decision input data and produces soft decision output data. The decoder 18 is coupled to a memory 20, whereby the memory 20 stores the decoded data, as will be discussed in more detail below. Once the data is decoded, the decoder 18 outputs the decoded data. It should be noted that the above modules are shown and described to simplify the description of the present invention and that the system shown in FIG. 1 is not limited to the components that are only shown or discussed.

The details of the encoder 10 of the present invention will now be discussed. As shown in FIG. 1, the LDPC code enters the encoder 10 as an input information vector codeword u. In the example, which will be referred to in describing the present invention, the information vector codeword u has a block length of 30,000 bits such that:

u=[u₀,u₁ . . . u_{29,999}]

As stated above, the LDPC code is a one-dimensional code and has a very large block length. In addition, the LDPC code has a significantly higher number of “zeros” than “ones”, which makes the encoding and decoding process for the LDPC very simple, efficient and fast.

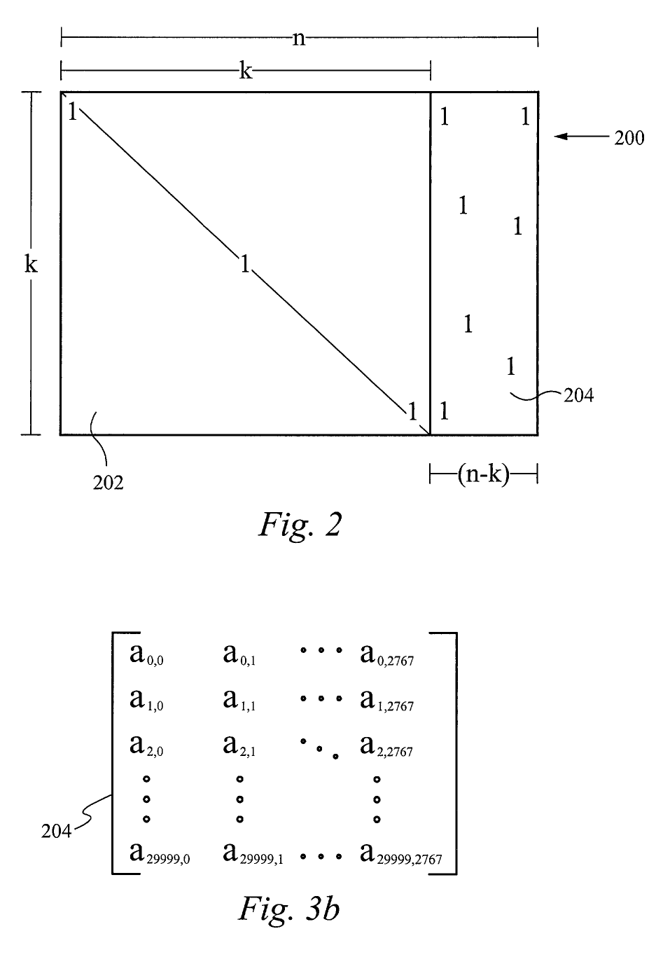

The encoder 10 of the present invention creates and utilizes a generator matrix 200 (FIG. 2) in conjunction with the one dimensional LDPC codeword to encode the input codeword u into an encoded output codeword v. The system 100 is configured such that the LDPC codeword will be encoded with a generator matrix 200 having a dimension (n,k), shown in FIG. 2. In the example, the generator matrix 200 in FIG. 2 is a (32768, 30000) matrix, whereby the generator matrix 200 includes a unit matrix 202 and a parity or redundant matrix 204. The unit matrix 202 preferably has k bit rows and k bit columns. Alternatively, the unit matrix 202 has an unequal number of rows and columns. In the present example, the unit matrix 202 has a size of 30000×30000 bits, due to the codeword u having a block length of 30,000 bits. Thus, the unit matrix 202 is preferably the same size k as the block length of the LDPC information vector codeword u. In the example, the parity matrix 204 has a size 30000×2768, in which the 2768 bits represent the redundant bits (n−k). The parity matrix 204 is preferably used to add the redundancy or parity vector a to the codeword u to form the output vector v, as will be discussed below.

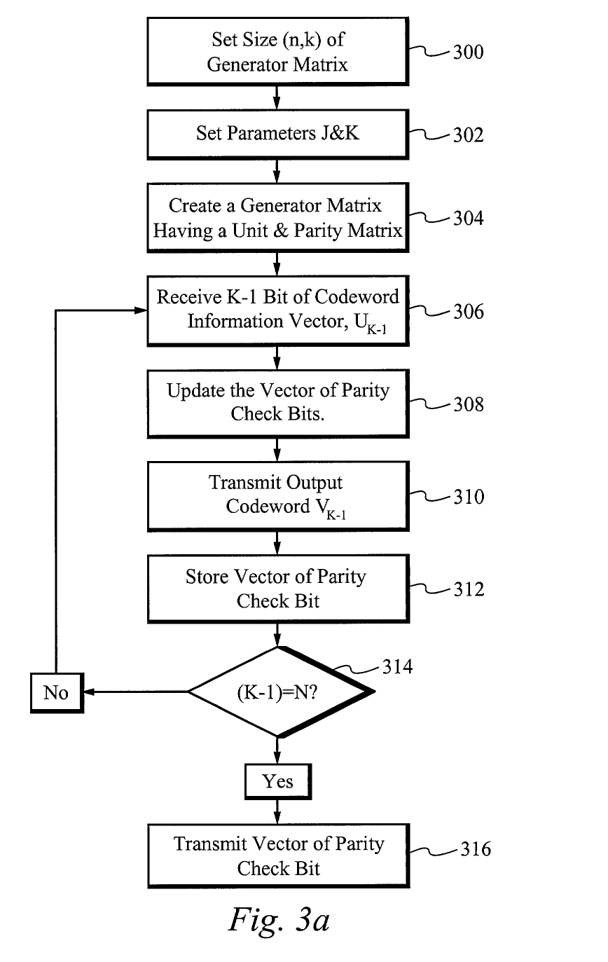

FIG. 3a illustrates a general flow diagram of the preferred encoding procedure in accordance with the present invention. In step 300, a generator matrix size 200 of (n,k) is set. In step 302, parameters J and K are set, as will be described in more detail below. Step 304 includes creating the generator matrix 200, wherein the generator matrix 200 includes a unit matrix 202 and parity matrix 204. In step 306, the encoder 10 receives the information codeword u which has Uₖ₋₁ bits. In step 308, the output redundant vector of the parity check bits (or output redundant bits) of the parity matrix 204 are set and updated, as will be discussed below. In step 310, the encoder 10 preferably transmits the output codeword vₖ₋₁ and stores in vector of the parity check bits (step 312). In step 314, the encoder determines whether the codeword bit n that is being processed is the last bit in the codeword vector u. If it is not, the encoder repeats steps 306 through 314. However, if the value of n is equal to the block length N of the codeword vector u, the encoder transmits the output redundant vector of the parity check bits, as shown in step 316.

More detail of the encoding procedure will now be discussed. Preferably, the encoder 10 of the present invention utilizes parameters J and K to place “ones” in the columns and rows, respectively, of the generator matrix 200. Since the LDPCs have a substantially random nature, the number of J and K “ones” placed in the generator matrix 200 are less compared to the total number of bits n and k of the generator matrix 200. It is preferred that between three and four J ones are inserted into each of the columns of the generator matrix 200. Similarly, it is preferred that between three and four K one are inserted into each of the rows of the generator matrix 200. Nonetheless, any number of J and K “ones” may be inserted into the generator matrix 200. Alternatively, the LDPC codes have an unequal J number throughout the parity check matrix 204. Alternatively, the LDPC codes also have an unequal K number throughout the parity check matrix. Thus, certain LDPC codes are constructed using unequal values of J for each row and unequal values of K for each column. This causes each parity check bit to be dependent on a different number of potentially different information bits and reduces the regularity in the code as well as causes the code to verge towards randomness. More detail concerning the construction of the generator matrix 200 is discussed below.

Once the J and K parameters are set, the encoder 10 encodes the LDPC codes by transforming the generator matrix 200 into systematic form. Preferably, the encoder 10 places some of the J and K “ones” diagonally across the unit matrix 202, as shown in FIG. 2, thereby placing “zeros” in the rest of the unit matrix 202. This configuration in the unit matrix 202 preferably allows the information vector codeword u to be combined only with the bits in the parity matrix 204. Alternatively, other configurations of the “ones” in the unit matrix 202 are used such that the codeword u is directly combined with the bits in the parity matrix 204.

Preferably, the remaining number of J and K “ones” which are not placed in the unit matrix 202 are then randomly placed within the parity matrix 204, as shown in FIG. 2. Alternately, the “ones” are arranged in a known, configured set, wherein the placement of the “ones” are transmitted along with the encoded data bits. These remaining “ones” are used by the encoder 10 in conjunction with each bit in the u codeword to encode the LDPC codeword into an encoded output vector v. Preferably, each bit in the information vector u is combined with each parity bit a in a corresponding row or column of the parity matrix 204. The parity matrix 204 shown in FIG. 3a includes 29,999 bit rows and 2767 bit columns, whereby the parity matrix 204 contains parity bit a_{0,0}, shown in the upper left hand corner of the matrix 204, to parity bit a_{29999,2767}, shown in the lower right hand corner of the matrix 204.

For the first output bit v₀ in the present example, the encoder 10 utilizes the input information bit u₀ and preferably directly sends the u₀ over the transmission channel 14, because the configuration of the diagonal “ones” in the unit matrix 202 allow the exact vector u to be seen in the 30,000 bit position of the output vector v. This is so, because for any vector x of size (1×n) multiplied by the identity matrix, I, of size (n×n), x′, produces x. Thus, the vector x is equivalent to x′.

Once the encoder 10 receives u₀, it sets and updates the output redundant vector V₍ₙ₋ₖ₎ of the parity check bits a, which in this example is 2768 bits long. Then the encoded bit is sent out as v₀, which is equal to u₀. The output redundant vector having parity check bits, v₃₀₀₀₀, v₃₀₀₀₁, . . . v₃₂₇₆₈ is preferably stored while the encoder waits for the next bit u₁ to be input to the encoder 10. The updates are done via the equations shown below:

$${v}_{0} = {u}_{0} , \\ {v}_{30000} = {u}_{0} \& {a}_{0 , 0}$$

$${v}_{30001} = {u}_{0} \& {a}_{0 , 1}$$

$$⋮$$

$${v}_{32767} = {u}_{0} \& {a}_{0 , 2767}$$

Once the encoder 10 has encoded and sent out the first output bit v₀, it preferably sends out the parity bits aₖ in the parity matrix 204 that are associated with the first input bit u₀. Thus, the encoder 10 forms an output redundant bit v_{30,000} by combining the information bit u₀ with the first parity bit in the first row of the parity matrix 204, which is a_{0,0}. The combination of the output redundant bit with the information bit is preferably done by logical multiplication. Similarly, the encoder 10 forms the output redundant bit v_{30,001} by combining the input information bit u with the second parity bit in the first row of the parity matrix 204, a_{0,1}. The encoder 10 then forms the output redundant bit v_{30,002} by combining the information bit u with the third parity bit in the first row of the parity matrix 204, a_{0,2}. This process repeats until the encoder 10 encodes V_{32,767} by combining the information bit u with the last parity bit in the first row of the parity matrix 204, a_{0,2767}. Preferably, the encoder 10 stores the output redundant bits in the memory 12, whereby the encoder 10 transmits the output redundant bit vector after the complete codeword u has been received and encoded by the encoder 10. Alternatively, the encoder 10 transmits the output redundant bits v₍ₙ₋ₖ₎ associated with the output codeword v₀ as they are generated.

Once the encoder 10 has formed the last output redundant bit for the output bit v₀, the encoder 10 forms the final output bit v₁ using bit 1 of the information vector codeword u₁. When the encoder 10 receives u₁, it updates the output redundant vector of the parity check bits. The output redundant vector of parity check bits is preferably stored while the encoder 10 waits for the next bit of the codeword u to be input to the encoder 10. The updates for the output codeword v₁ are done via the equations shown below:

$${v}_{1} = {u}_{1} , \\ {v}_{30000} = {v}_{30000} ⊕ {u}_{1} \& {a}_{1 , 0}$$

$${v}_{30001} = {v}_{30001} ⊕ {u}_{1} \& {a}_{1 , 1}$$

$$⋮$$

$${v}_{32767} = {v}_{32767} ⊕ {u}_{1} \& {a}_{1 , 2767}$$

where the combination of the output redundant bit with the information bit is preferably done by logical addition. As shown above, the final output bit is sent out as v₁ which is equivalent to u₁. In other words, for the second final output bit v₁, the encoder 10 utilizes the information bit u₁ and sends the vector bit u₁ over the transmission channel 14, because the configuration of the diagonal “ones” in the unit matrix 202 allow the exact vector u to be seen in the first 30000 positions of the output vector v. Once the encoder 10 has encoded and sent out v₁, it sends out the parity bits a associated with the output bit v₁ using the equations above. The encoder 10 forms the output redundant bit v₍ₙ₋ₖ₎ by combining the input information bit u₁ with the first parity bit in the second row of the parity matrix 204, which is a_{1,0}. The encoder 10 preferably combines the information bit u₁ with the parity bit a_{1,0} by utilizing a logical multiplication technique. The encoder 10 then updates the output redundant bit v₃₀₀₀₀ by performing a logical addition technique between the output redundant bit and the redundant codeword bit v₃₀₀₀₀ from the last bit of the codeword u.

Similarly, the encoder 10 forms the output redundant bit v_{30,001} for output bit v₁ by combining the information bit u₁ with the second parity bit in the second row of the parity matrix 204, which is a_{1,1}. The encoder 10 then updates the output redundant bit v₃₀₀₀₁ by performing a logical addition technique between the output redundant bit and the output redundant codeword bit v₃₀₀₀₁. Again, the encoder 10 forms the output redundant bit V_{30,002} for bit v₁ by combining the information bit u₁ with the third parity bit in the second row of the parity matrix 204, which is a_{1,2}, and performing a logical addition technique of the combination with the output redundant bit v_{30,002}. This process repeats for bit v₁ until the encoder 10 encodes all the output redundant bits v_{32 767} by combining the information bit u₁ with the last parity bit in the second row of the parity matrix 204, which is a_{1,2767} and updating the product with the output redundant bit v_{32,767}.

Once all of the 30000 u information bits have been input and encoded for this example, the 2768 output redundant bits are preferably output following the information bits v. Thus, in the present example, the output codeword v is:

v=[u₀, u₁, u₂ . . . u_{29,999}, v₃₀₀₀₀, v₃₀₀₀₁, . . . v₃₂₇₆₇]

As stated above, each bit is formed in the final output codeword v by using the corresponding parity bit from each column for the corresponding row in the parity matrix, 202. Alternatively, the parity bits used to form the output redundant bits in the codeword v are taken along a column in the parity matrix 202, rather than a row. In an alternate embodiment, the parity bits used to form the output redundant bits in the codeword v are taken from a combination of the rows and columns of the parity matrix 202, i.e. a diagonal configuration.

The details of how the generator matrix 200 is constructed for the LDPC will now be discussed. It should be noted that although the discussion regarding the encoding of the codewords relates to LDPC codes, the encoding procedure and method may be used with other types of error correction codes. As stated above, the encoder 10 is given parameters J and K units. Preferably, the value of K is greater than the value of J. The generator matrix 200 includes the unit matrix 202 having a size k×k, whereby the unit matrix 202 has a diagonal of “ones” and the remaining bits of “zeros.” In addition, the generator matrix 200 includes an initial parity matrix 204 which represents J lines from k sub matrixes, whereby the parity matrix 204 is a result of the cyclic rearrangement of columns of the diagonal in the unit matrix 202. Further, a set of rows or columns in the parity matrix 204 that are associated with the parameters J and K are appropriate to some arbitrary line of sub matrixes, which is designated as a strip. It is preferred that each column of any strip contains equally one J or K unit. Accordingly, each column of parity matrix 204 includes J units and each row of the parity matrix 204 includes K unit matrices.

This initial parity matrix 204 generates a linear code having a block length of N with a data rate of R=1−(J/K). An approximation is preferably used because, the initial parity matrix 204 has linearly dependent rows. Thus, the number of information symbols appears more than k×(N−J) such that the block length N of the code has the maximum information bits within the block. If K>k, it is possible to choose cyclic rearrangements of columns of diagonal sub matrixes in such a manner that parity matrix 204 will set J orthogonal parity checks for each symbol of the code. Thus, such a matrix having an orthogonal property for parity checks allows use of the initial parity matrix 204 to generate subsequent parity matrixes. This is preferably done by rearranging the columns in each strip of the initial parity matrix, whereby the number of attempts to rearrange the columns in each strip is predetermined.

For every iteration, it is preferred that two columns in a given strip are randomly chosen and their positions are interchanged. Following, the orthogonality of the parity matrix 204 is checked. If the orthogonality of the parity matrix 204 is met, the arrangement of columns is kept. However, if the orthogonality of the parity matrix 204 is not met, the arrangement of the columns is cancelled. After all the strips in the parity matrix have been rearranged and the desired parity matrix 204 is not met, a new parity matrix 204 is formed having orthogonal properties to the initial parity matrix 204. Such a new parity matrix would give better results for LDPC codes that are to be transmitted over a channel having white additive Gaussian noise. After using the standard procedure of rearranging the columns and linear operation with the rows, a parity matrix Hs is formed. The parity matrix Hs preferably is in a systematic form, Hₛ=[E, I_{NR}], where I_{NR} is an identity matrix having a size of (NR×NR), and E is an arbitrary matrix. It should be noted that Hs is not a low density matrix.

The decoder 18 in accordance with the present invention will now be discussed. As stated above, the decoder 18 is preferably a SISO decoder which uses hard decision values and soft decision values provided by the demodulator 16. For the encoded codeword v received from the transmission channel 14, the demodulator 16 generates two vectors, one vector of hard binary decisions for each symbol x=(x₀, x₂ . . . , x_{N-1}) and one soft decision vector of reliability symbols E=(E₀, E₂, . . . , E_{N-1}), where the value of the reliability of the ith symbol of size Eᵢ is proportional to the logarithmic likelihood ratio of the symbol xᵢ. Using the received vector, x, the decoder 18 calculates the syndrome s=(s₀, s₂, sᵣ₋₁), where r is number of rows of the parity matrix 204.

The decoding algorithm includes a predetermined number of iterations. For each iteration, each row of the parity check matrix 204 is preferably consecutively processed, whereby the each bit in the syndrome, s, is calculated and the corresponding reliability value of the vector, E, is updated. In an alternate embodiment, the system 100 may utilize more than one decoder (not shown) in parallel to decode the encoded codewords. Parallel decoders are preferably used to decode blocks having more than one dimension, such as LDTPCs, as will be discussed below. This is evident mainly from the way the decoding algorithm in the decoder 18 works by first evaluating the syndromes s in order. Then, the soft metric vectors are calculated using these syndromes. It is noted that, in the decoding algorithm, the reliability symbols E are positive. If a change occurs to the reliability values whereby the reliability value E becomes negative, the hard decision value x associated with the reliability value E is changed.

The detailed procedure of decoding and processing a row of the LDPC will now be discussed. It should be noted that although the discussion regarding the decoding of the codewords relates to LDPC codes, the decoding procedure and method may be used with other types of error correction codes. Before processing of a jth row, there are current values of hard decision vectors, reliability vectors and syndrome vectors in the decoder 18. After processing the jth row, the modified values of the hard decision vectors, reliability vectors and syndrome vectors are obtained and updated. Denote as n(j, k), the position of the kth one in the jth row. Thus, n(j, 1), n(j, 2), . . . , n(j, K) are the positions of the “ones” in each row j. In addition, the set of reliability vectors for row j are E_{n(j,1)}, E_{n(j,2),} . . . , E_{n(j,K)}. For simplicity, the reliability vectors for E_{n(j,K)} is designated as E₁, E₂ . . . , E_{K}.

Processing of each row includes the step of setting Eₖ₁ to be the minimal reliability value and Eₖ₂ to be the next reliable value. The following step depends on the value of component of the syndrome vector s that is appropriate to the given row, j. For instance, if sⱼ=0, then the values of the components in the reliability vectors are set to (Eₖ₁+Eₖ₂) in positions k₁ and k₂. In all of the other positions, the reliability component values are increased by Eₖ₁. However, if sⱼ=1, then the values of the components in the reliability vectors are set to (Eₖ₂−Eₖ₁) in positions k1 and k2. In all of the other positions, the values are reduced by Eₖ₁. The components of the hard decision vectors x are then updated as necessary, whereby the syndrome s is recalculated for the next iteration.

After processing all the rows of the parity matrix, it is preferred to normalize the reliability values E. This is done in order to prevent loss of any information content in the codeword v. For instance, the maximum reliability values for the whole codeword may be reduced. However, this depends on the amount of noise present in the transmission channel 14. The decoding process is complete if the syndrome vector s is equal to 0. If the decoder stops before the syndrome vector s is equal to 0, then a block error is detected in the codeword v .

For decoding, another matrix H, received from H′, is used preferably with the same rearrangement of columns as matrix Hₛ, but without a linear combination of the rows. It should be noted that matrix H is a low density matrix. The generating matrix of the low density code is designated G=[I_{N(1-R),}E^{T}], where I_{N(1-R)} is the identity matrix having a size N(1−R)×N(1−R). It is preferred that matrix H is a parity check matrix for the matrix G. To obtain the code word, from the matrix G, the information word is multiplied by the matrix G. This results in a systematic code word including the unchanged information bit portion and parity or redundant bit portion.

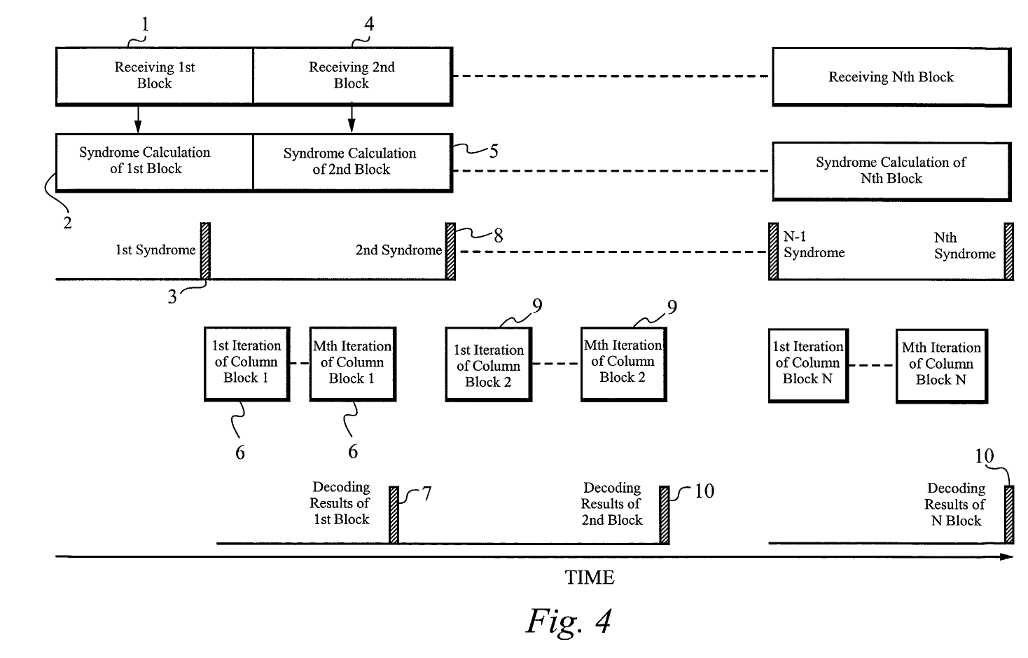

FIG. 4 illustrates a general timing diagram of the decoding process in accordance with the present invention. Step 1 shows that the first block of data is received in the decoder 18. In step 2, the syndrome is calculated for the first codeword. In step 3, a result for the first syndrome of the first block is reached. At this time, in step 4, the second block of data is received in the decoder 18. In step 5, the syndrome is calculated for the second codeword. Meanwhile, in step 6, the decoder 18 is concurrently performing an iterative decoding scheme on block 1 for a “m” number of iterations. In step 7, the decoded results of the first block are calculated. It is preferred that the decoder 18 stores the decoded results in memory 20 while it continues to decode the subsequent blocks of data. Following, step 8 shows that a result for the second syndrome is reached. Following, the decoder receives the subsequent blocks of encoded data from the encoder (not shown). Meanwhile, in step 9, the decoder 18 is concurrently performing an iterative decoding scheme on block 2 for “m” number of iterations. Following, in step 10 the decoding results are provided for the second block. This process is repeated and continues for N number of blocks of data that are being received.

In an alternate embodiment, the LDPC codes are configured in a product code fashion, such that the LDPC codes will be encoded and decoded as a turbo product code. Thus, in the alternate embodiment, the present invention uses an LDPC code inside a product code to make a low density turbo product code or LDTPC. Although the LDTPCs are encoded a different way than traditional turbo codes, they are decoded as a turbo code.

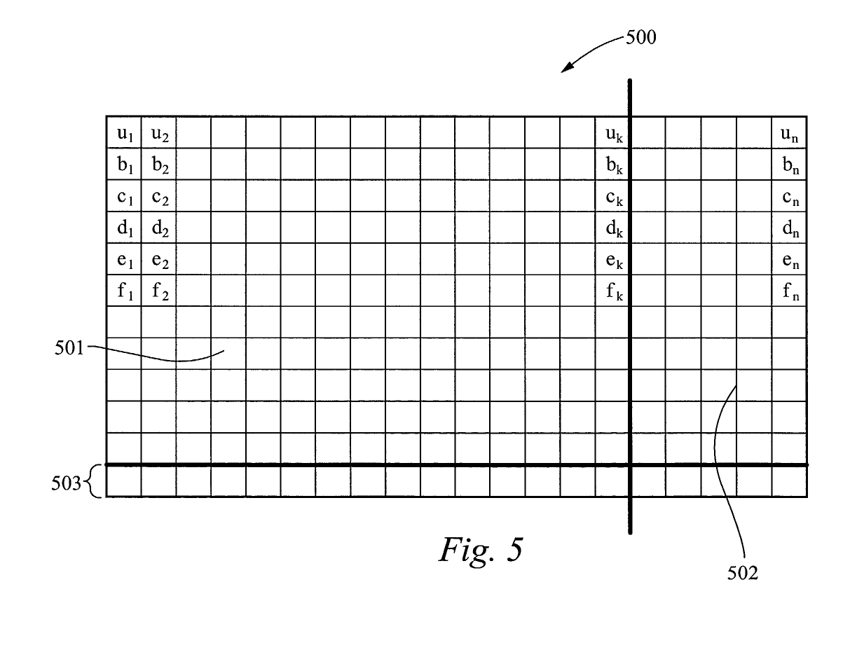

In the alternate embodiment utilizing the LDTPCS, the information vector codewords u, b, c, d, etc. are received by the encoder 10. The encoder 10 then generates a block matrix 500 in which all the incoming LDPC codewords are organized per row. As shown in FIG. 5, all the k bits of the codeword u are placed along the first row in the unit matrix portion 501 of the block matrix 500. FIG. 5 also illustrates that all the parity (n−k) bits of the codeword u are placed in the parity matrix 502 of the block matrix 500. In addition, as shown in FIG. 5, all the k bits of the codeword b are placed along the second row in the unit matrix portion 501 of the block matrix 500 and so on. FIG. 5 also illustrates that all the parity (n−k) bits of the codeword b are placed in the parity matrix 502 of the block matrix 500.

Once all the information vector codewords are read and arranged in the block 500, they are encoded using the methods discussed above regarding the encoding of the LDPC codes. Following, a parity check bit row 503 is added to the last row of the block 500, as shown in FIG. 5. The parity check bit row 503 is preferably added by the encoder 10, whereby the encoder generates the parity check bit row 503 by encoding each codeword along the corresponding row or column. Once the parity check bit row 503 is added, the encoded bits are sent across the transmission channel 14. In the alternate embodiment, the order of the bits is arbitrary as long as the bits, once received or decoded, can be lined up again in the same form.

The decoder 18 can decode the LDTPC code by using the same iterative decoding scheme discussed above in regard to the LDPC codes and parity check codes. However, in addition to decoding all the rows of the LDTPC block, the decoder will complete one additional decoding of the columns using the parity check bit row 503.

In an alternative embodiment, the encoder 10 in the system 100 includes one or more parallel processors to significantly reduce the number of operations to encode one input bit in the information vector U. The reduction is dependent on the number of parallel processors used in the encoder 10. In an another alternative embodiment, more than one encoder may be used (not shown) to encode more than one input bit at a time and carry out simultaneous processing of the parity rows or alternately, columns, in the parity matrix 202. It should be noted that parallel processors and decoders are preferably used to decode blocks having more than one dimension.

In an alternate embodiment, decoding of the codewords is performed with prior knowledge of all the constituent codes. This is performed by taking a set of known but random LDPC codes in the construction of the LDTPCs such that the block structure remains in tact and the parity codes work properly. The uniqueness of the constituent codes enables the system 100 to have full control over the security of the transmitted data. This is achieved before compromise by selecting a unique set. After the data has been compromised, this unique set is adjusted to a new unique set which has been defined in a predetermined way such that the receiving end is able to understand the set.

In addition, use of differing constituent codes throughout the block allows better error protection. Thus, a certain error correction scheme is performed for a certain portion of the block, whereas a different error correction scheme is performed for another part of the block. However, the transmitting end and receiving end of the system 100 are given sufficient information such that both ends are able to process the exact codes used in the block as well as know exactly where in the block the different error correction schemes are to be used.

In another alternative embodiment, the above method is used to achieve block synchronization. Block synchronization is applied by taking a known unique set of constituent codes and calculating the reliability values of the decoded word in a known channel. Synchronization occurs when the reliability values indicate a high probability that convergence has occurred for the block. Decoding will be performed accurately when the blocks of data are synchronized. However, multiple decoding of the block may be needed if there is an initial lock up of the decoder. Nonetheless, re-synchronization of the block is relatively simple if slippages occur only for a few bits after the initial lock up.

Another alternate embodiment of the present invention allows the system 100 to counteract any errors in a particular column or row of the product code by constructing the product code to have shifts within. The alternative embodiment of the present invention uses shifts of different LDPC codes for the rows to minimize chances of receiving similar errors in the same rows and/or columns. Alternatively, the present uses shifts of the same LDPC code in the rows and/or columns. The shifts may include moving successive rows and/or columns to the right or left by any number of bit positions. Thus, the use of shifts in the present invention reduces the risk of overloading the parity check matrix. The use of shifts of the LDPCs enables the system 100 to detect errors as well as correct errors. Therefore, the system 100 is able to avoid the use of cyclic redundancy checking to detect errors in a soft decision decoding system, whereby the data rate is able to be kept to the highest possible rate.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modification s may be made in the embodiment chosen for illustration without departing from the spirit and scope of the invention.

What is claimed is:

1. A method of encoding a one dimensional input codeword into an output codeword, wherein the output codeword includes an output codeword bit comprising the steps of:
a. receiving the input codeword, wherein the input codeword includes an input codeword bit;
b. creating a generator matrix, wherein the generator matrix includes a parity matrix having a plurality of parity bits;
c. combining the input codeword bit and a corresponding parity bit from the plurality of parity bits, thereby generating an output redundant bit associated with the output codeword bit;
d. transmitting the input codeword bit; and
e. transmitting the output redundant bit.
